(19) United States
(12) Patent Application Publication
(10) Pub. No.: US 2015/0010867 A1
(43) Pub. Date: Jan. 8, 2015

(54) METHOD FOR MANUFACTURING ELECTROPHORESIS GEL AND APPARATUS FOR MANUFACTURING ELECTROPHORESIS GEL

(71) Applicant: Sharp Kabushiki Kaisha, Osaka-shi, Osaka (JP)

(72) Inventors: Hiroshi Ohki, Osaka-shi (JP); Hiroshi Yamaki, Osaka-shi (JP); Tsuyoshi Tanaka, Osaka-shi (JP); Yoshiyuki Ishida, Osaka-shi (JP); Yutaka Unuma, Osaka-shi (JP); Yuji Maruo, Osaka-shi (JP)

(73) Assignee: Sharp Kabushiki Kaisha, Osaka-shi, Osaka (JP)

(21) Appl. No.: 14/377,915

(22) PCT Filed: Feb. 26, 2013
(86) PCT No.: PCT/JP2013/054897

§ 371 Date: Aug. 11, 2014

(30) Foreign Application Priority Data
Mar. 5, 2012 (JP) 2012-048444
Mar. 26, 2012 (JP) 2012-070180

(51) Int. Cl. G03F 7/20; C08F 2/04; B01J 19/08; C08F 2/48

(52) U.S. Cl. CPC G03F 7/20; C08F 2/48; C08F 2/04; B01J 19/08; B01J 2219/0877
USPC 430/320; 522/175; 524/850; 422/131

(57) ABSTRACT

An electrophoresis gel, in which a good pH gradient or concentration gradient of a gel-forming monomer is formed, is produced. In addition, the production efficiency of an electrophoresis reaction tool is improved and the production processes are simplified. At least one of a first process to add a gel-forming monomer to a first solution containing an initiator to initiate polymerization of the gel-forming monomer by external energy in such a way that a pH gradient or concentration gradient of the gel-forming monomer is formed and a second process to initiate the polymerization of the above-described gel-forming monomer in the first solution, to which the above-described gel-forming monomer has been added, by using the above-described external energy is included.

### TECHNICAL FIELD

The present disclosure relates to technologies of a method for manufacturing an electrophoresis gel having a pH gradient or gel concentration gradient and an apparatus for manufacturing an electrophoresis gel.

The present disclosure contains subject matter related to that disclosed in Japanese Priority Patent Application JP 2012-048444 filed in the Japan Patent Office on Mar. 5, 2012 and Japanese Priority Patent Application JP 2012-070180 filed in the Japan Patent Office on Mar. 26, 2012, the entire contents of which are hereby incorporated by reference.

### BACKGROUND ART

In recent years, electrophoresis gels having a pH gradient or gel concentration gradient, e.g., immobilized pH gradient (IPG) gels used for isoelectric focusing (IEF) and gradient gels used for sodium dodecyl sulfate-polyacrylamide gel electrophoresis (SDS-PAGE), have been utilized actively. Technologies described in PLTs 1 and 2 are mentioned as a technology to produce such an electrophoresis gel.

PTL 1 discloses a method for producing an electrophoresis gel plate, in which gel concentration is partly different, by ejecting a plurality of gel solutions adjusted to have gel concentrations different from each other on a plate with an ink-jet head and drying the gel solutions concerned.

Also, PTL 2 discloses a method for manufacturing an electrophoresis reaction tool constructed by immobilizing an electrophoresis gel to a base material, wherein the method for manufacturing an electrophoresis reaction tool includes a first ejection process to form a liquid pool by ejecting a liquid on the surface, to which the above-described gel is immobilized, of the above-described base material and a second ejection process to eject a gel solution to the above-described liquid pool after the above-described first ejection process.

Also, PTL 3 discloses a sample separation tool serving as a separating apparatus used for two-dimensional electrophoresis and including an insulating material to store a second medium for the purpose of further separating a separated sample, which has been separated in a first direction in a first medium, in a second direction different from the first direction.

### CITATION LIST

### Patent Literature

PTL 1: Japanese Unexamined Patent Application Publication No. 2004-77393 (published on Mar. 11, 2004)
PTL 2: Japanese Unexamined Patent Application Publication No. 2012-2739 (published on Jan. 5, 2012)
PTL 3: Japanese Unexamined Patent Application Publication No. 2007-64848 (published on Mar. 15, 2007)

### SUMMARY OF INVENTION

### Technical Problem

The accuracy of the result of electrophoresis by using an electrophoresis gel having a pH gradient or gel-forming monomer concentration gradient is dependent on the gradient concerned. Therefore, a technology to produce an electrophoresis gel, in which a good pH gradient or gel-forming monomer concentration gradient is formed, is very useful.

The present disclosure has been made in consideration of the above-described issues and it is a main object to provide a technology to produce an electrophoresis gel in which a good pH gradient or gel-forming monomer concentration gradient is formed.

In this regard, electrophoresis is a phenomenon in which charged particles or molecules move by application of a voltage to a medium. In particular, in molecular biology and biochemistry, the electrophoresis is important as a technique to separate biopolymers, e.g., proteins, DNA, and RNA.

In recent years, proteome analysis has been noted as post-genome analysis. This proteome analysis refers to large-scale research on the structure and the function of a protein. Usually, in order to analyze proteome, initially, a sample containing a plurality of proteins is separated into the individual proteins. At this time, two-dimensional electrophoresis is frequently used as one of techniques to separate proteins.

The two-dimensional electrophoresis is a technique to two-dimensionally separate proteins by two-step electrophoresis. For example, in a first-dimension step, proteins are separated on the basis of the individual charges by isoelectric focusing (IEF) and in a second-dimension step, proteins are separated on the basis of the individual molecular weights by sodium dodecyl sulfate-polyacrylamidegel electrophoresis (SDS-PAGE). Such two-dimensional electrophoresis exhibits a very high resolving power and can separate several thousands or more of types of proteins with a high resolving power.

As for IEF serving as first-dimension electrophoresis, for example, immobilized pH gradient (IPG) method having excellent reproducibility and resolution is used. In the immobilized pH gradient method, an immobilized pH gradient gel (IPG gel) is used as a first-dimension electrophoresis gel.

In PDS-PAGE serving as second-dimension electrophoresis, for example, an agarose gel or a polyacrylamide gel is used as a PDS-PAGE gel. Also, in many cases, a homogeneous gel of acrylamide solution having a uniform concentration is used as the polyacrylamide gel. However, in the case where separation of proteins having a wide range of molecular weight distribution is intended, a gradient gel in which the concentration of the acrylamide solution grades from a high value to a low value is used.

These IPG gel and PDS-PAGE gel are formed by, for example, coating of plastic or glass or pouring of a gel solution into a form (for example, molds, such as, a space between glass substrates opposite to each other with spacers therebetween) so as to cast. The IPG gel and the PDS-PAGE gel are used for a first-dimension electrophoresis reaction tool to induce first-dimension electrophoresis and a second-dimension electrophoresis reaction tool to induce second-dimension electrophoresis. In this regard, the IPG gel and the PDS-PAGE gel are formed from a gel solution by a radical polymerization reaction. In order to initiate the radical polymerization reaction, ammoniumpresulfate (APS) is used as a polymerization initiator and N,N,N′,N′-tetramethylethylenediamine (TEMED) is used as a polymerization promoter.

In the sample separation tool described in PTL 3, it is necessary that the first-dimension electrophoresis reaction tool and the second-dimension electrophoresis reaction tool be produced manually by a user, and an improvement in the production efficiency of the reaction tool is an issue.

Also, in production of the first-dimension electrophoresis reaction tool in PTL 3, there is complication because a sheet provided with an IPG gel is formed into the shape of a strip and, thereafter, is immobilized to the surface of a tabular insulating material. Therefore, simplification of the production processes of the electrophoresis reaction tool has been desired.

The present disclosure has been made in consideration of the above-described issues, and it is an object to provide a method for manufacturing an electrophoresis reaction tool and an apparatus for manufacturing an electrophoresis reaction tool, wherein the production efficiency of the electrophoresis reaction tool can be improved and the production processes are simplified.

### Solution to Problem

A method for manufacturing an electrophoresis gel, according to an aspect of the present disclosure, is characterized by including at least one of adding a gel-forming monomer to a first solution containing an initiator to initiate polymerization of the gel-forming monomer by external energy in such a way that a pH gradient or concentration gradient of the gel-forming monomer is formed, as a first process, and initiating the polymerization of the above-described gel-forming monomer in the first solution, to which the above-described gel-forming monomer has been added, by using the above-described external energy, as a second process.

Also, the method for manufacturing an electrophoresis gel, according to an aspect of the present disclosure, is characterized in that the above-described first process is performed on a base material to support an electrophoresis gel and the above-described gel-forming monomer is added by using an ink-jet device.

Also, the method for manufacturing an electrophoresis gel, according to an aspect of the present disclosure, is characterized in that the external energy is light or heat.

Also, the method for manufacturing an electrophoresis gel, according to an aspect of the present disclosure, is characterized by further including, before the above-described first process, applying a surface treatment to the above-described base material, as a third process, and storing the above-described first solution in a region subjected to the above-described surface treatment, as a fourth process.

Also, the method for manufacturing an electrophoresis gel, according to an aspect of the present disclosure, is characterized in that a hydrophilic treatment and formation of a plurality of concavities and convexities are performed in the above-described fourth process.

Also, the method for manufacturing an electrophoresis gel, according to an aspect of the present disclosure, is characterized by further including disposing a shielding film to block the above-described external energy on the first solution, to which the above-described gel-forming monomer has been added, as a fifth process, and developing the above-described first solution after the above-described second process and removing the above-described first solution in the region shielded from the above-described external energy, as a sixth process.

Also, the method for manufacturing an electrophoresis gel, according to an aspect of the present disclosure, is characterized in that the above-described base material is formed from at least two base material pieces separable from each other.

Also, the method for manufacturing an electrophoresis gel, according to an aspect of the present disclosure, is characterized by further including separating the above-described base material, after the above-described sixth process, into the above-described at least two base material pieces, as a seventh process.

Also, an apparatus for manufacturing an electrophoresis gel, according to an aspect of the present disclosure, is characterized by including an addition device to add a gel-forming monomer to a first solution containing an initiator to initiate polymerization of the gel-forming monomer by external energy in such a way that a pH gradient or concentration gradient of the gel-forming monomer is formed and a polymerization initiation device to initiate the polymerization of the above-described gel-forming monomer in the first solution, to which the above-described gel-forming monomer has been added, by using the above-described external energy.

### Advantageous Effects of Invention

According to the present disclosure, the process to form the gradient of the gel-forming monomer and the process to allow the gel-forming monomer to gel are performed completely separately and gelation can be controlled simply because polymerization is initiated not by addition of a reagent but by applying the external energy, so that an electrophoresis gel, in which a good pH gradient or gel-forming monomer concentration gradient is formed, can be produced.

Meanwhile, the method for manufacturing an electrophoresis reaction tool and the apparatus for manufacturing an electrophoresis reaction tool, according to the present disclosure, exhibit effects of improving the production efficiency of the electrophoresis reaction tool and simplifying the production processes thereof because radiation energy is applied to a predetermined region of a mixed material of a monomer to form a gel and a photoresist material so as to allow the monomer in the region irradiated with the radiation energy to gel and remove the mixed material in the region not irradiated with the radiation energy through development.

### BRIEF DESCRIPTION OF DRAWINGS

FIG. 1 shows side-sectional views illustrating a method for manufacturing an electrophoresis gel according to an embodiment of the present disclosure.

FIG. 2 shows perspective views illustrating a method for manufacturing an electrophoresis gel according to an embodiment of the present disclosure.

FIG. 3 shows perspective views illustrating a method for manufacturing an electrophoresis gel according to an embodiment of the present disclosure.

FIG. 4 is a function block diagram illustrating the schematic configuration of an apparatus for manufacturing an electrophoresis gel according to an embodiment of the present disclosure.

FIG. 5 shows perspective views illustrating the production processes of an electrophoresis reaction tool according to an embodiment of the present disclosure.

FIG. 6 shows sectional views illustrating the production processes of an electrophoresis reaction tool according to an embodiment of the present disclosure.

FIG. 7 shows diagrams illustrating the production processes of a plurality of electrophoresis reaction tools according to another embodiment of the present disclosure.

FIG. 8 is a perspective view illustrating an electrophoresis reaction tool according to another embodiment of the present disclosure.

### DESCRIPTION OF EMBODIMENTS

### First Embodiment

The present disclosure provides a method for manufacturing an electrophoresis gel used for electrophoresis and a manufacturing apparatus. According to the present disclosure, although not limited to this, electrophoresis gels in which a pH gradient or gel concentration gradient is formed, for example, immobilized pH gradient (IPG) gels usable for isoelectric focusing (IEF) and gradient gels usable for sodium dodecyl sulfate-polyacrylamide gel electrophoresis (SDS-PAGE), can be produced favorably.

Meanwhile, the electrophoresis gels produced according to the present disclosure can be favorably used for electrophoresing preparations taken from, for example, biological materials, e.g., biological individuals, body fluids, cell lines, tissue culture materials, and tissue pieces. In particular, uses for electrophoresing proteins, polypeptides, and polynucleotides can be made favorably.

In this regard, in the present specification, a tool in which an electrophoresis gel is provided with a base material to support the electrophoresis gel may be referred to as an electrophoresis reaction tool.

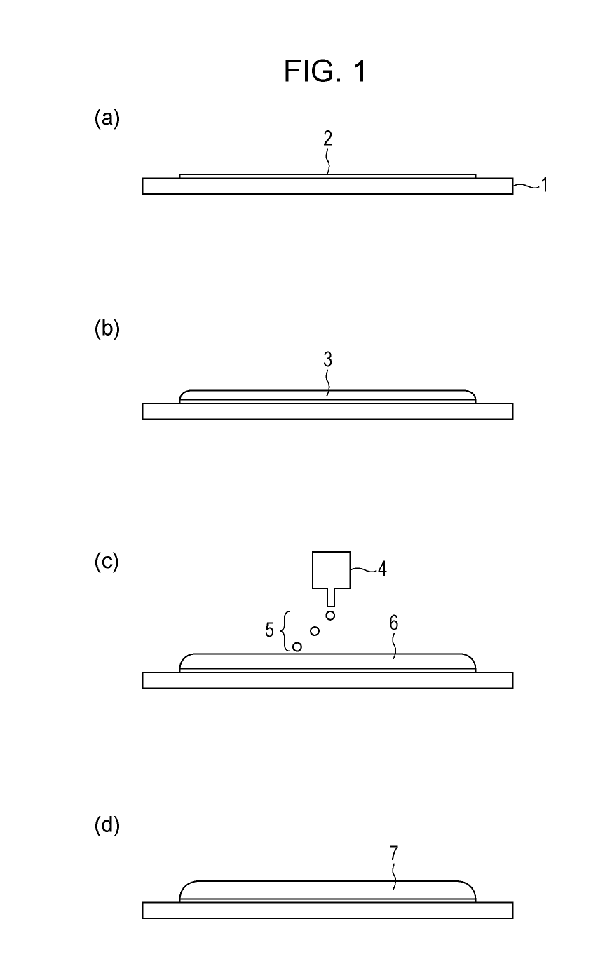

Next, a method for manufacturing an electrophoresis gel, according to an embodiment of the present disclosure, will be described with reference to drawings. FIG. 1 shows side-sectional views illustrating a method for manufacturing an electrophoresis gel, according to the present embodiment. In the method for manufacturing an electrophoresis gel, according to the present embodiment, a surface treatment process, a first solution storing process, a gradient formation process, and a polymerization initiation process are executed in that order.

In this connection, in the present embodiment, as an example, the case where an electrophoresis gel 7 is produced will be described, wherein an acrylamide or an acrylamide derivative is used as a gel-forming monomer and a 4% polyacrylamide gel, which is one of typical electrophoresis gels, is formed. However, the present disclosure is not limited to this and known gels, e.g., polyacrylamide gels having different concentrations and agarose gels, which are used as electrophoresis gels in the field concerned, can be used.

Also, in the present embodiment, reagents to form the 4% polyacrylamide gel are, for example, a 30% acrylamide mixed solution (acrylamide+N,N′-methylenebisacrylamide), a 1-M tris-hydrochloric acid buffer solution (Tris-HCl), riboflavin, and pure water. The acrylamide mixed solution is a gel-forming solution in which an acrylamide to form a main skeleton of a gel and N,N′-methylenebisacrylamide to cross-link the main skeleton of the gel are mixed. The tris-hydrochloric acid buffer solution is a buffer and riboflavin is a photopolymerization initiator. In the present embodiment, these reagents to form the gel are mixed in two steps. However, the number of mixing is not specifically limited insofar as the gradient formation process and the polymerization initiation process are executed.

(Surface Treatment Process)

In the surface treatment process, a base material 1 is subjected to a surface treatment to form a gel-forming region 2 (FIG. 1 (a)).

The base material 1 is to support an electrophoresis gel 7 produced and the electrophoresis gel 7 is formed and immobilized to at least part of the surface thereof. The shape of the base material 1 is not specifically limited, and an appropriate shape, for example, the shape of a flat plate or the shape of a tray, can be employed. The material of the base material 1 is not specifically limited and, for example, glass, resin, or ceramic is mentioned. Examples of glass include quartz glass and alkali-free glass. Examples of resin include polyethylene terephthalate (PET) and polymethyl methacrylate (PMMA). Examples of ceramic include alumina and low temperature co-fired ceramic.

The gel-forming region 2 is a region to store each of a first solution 3 and a gel solution 6 described later and finally immobilize the electrophoresis gel 7. The above-described surface treatment forms such a gel-forming region 2 on the base material 1.

For example, the surface treatment may be applied in such a way that the gel-forming region 2 has hydrophilicity and the other region has hydrophobicity. That is, the hydrophilic region has good wettability with a liquid and the hydrophobic region has poor wettability with a liquid. Therefore, for example, in the case where a liquid is ejected on the base material, the liquid forms a liquid pool while spreading on the region having good wettability, and the liquid pool does not spread any more easily on the region having poor wettability. Consequently, the range of formation of a liquid pool of the first solution 3 described later can be controlled by forming the hydrophilic gel-forming region 2 and a hydrophobic region surrounding the gel-forming region 2 on the base material. Also, peeling of the electrophoresis gel 7 from the base material 1 can be prevented.

Meanwhile, it is favorable that the gel-forming region 2 have strong adhesive force (bonding force) to the electrophoresis gel 7. For example, a plurality of physical concave and convex shapes are disposed in the gel-forming region 2, and the adhesive (bonding) force between the electrophoresis gel 7 and the base material 1 is improved by an anchor effect. Such a physical shape can increase the surface area of the base material 1 to a great extent, and the adhesive (bonding) force can be increased. A convex shape formed by depositing fine particles may be used, a concave shape formed by nanoimprinting may be used, or a combination thereof may be used.

That is, as for the surface treatment, for example, hydrophilic surface treatments, e.g., hydrophilic polymer coating, an oxygen plasma treatment, glow discharge, arc discharge, a sulfonation treatment, and a nitration treatment, and surface treatments, e.g., a plasma graft polymerization film, nanodot formation, and nanoimprinting, can be used, although not limited to them. In particular, it is favorable that a surface treatment in which fine particles being composed of an inorganic material, e.g., silicon oxide, and having a diameter of several nanometers to several tens of nanometers are deposited by chemical vapor deposition (CVD) or the like and the hydrophilic surface treatment by oxygen plasma or the like be combined from the viewpoint of effects of restricting the region to be provided with the liquid pool of the first solution 3 and, in addition, improving the adhesion of the produced electrophoresis gel 7, so as to suppress peeling of the gel. Also, the hydrophilic surface treatment by oxygen plasma or the like and the concave portion formation by the nanoimprinting method may be combined. Also, it is favorable that the surface treatment be performed after regions other than the region to be provided with the gel-forming region 2 are subjected to masking.

In this regard, the gel-forming region 2 may be a region in which the first solution 3 is stored and to which the electrophoresis gel 7 adheres in the predetermined region on the base material 1, as described above, and may be regions provided with, for example, concave structures having a depth of several micrometers to several hundred micrometers (mortise structure), convex structures (protuberance structure), fine concave and convex structures, and a structure which is a combination of these structures besides the above-described region subjected to the surface treatment. That is, in the case where the base materials 1 having such structures are used, the surface treatment process is not necessary executed. Meanwhile, in the case where the base material 1 does not have such structures, the surface treatment process may be omitted.

(First Solution Storing Process)

In the first solution storing process, the first solution 3 is stored in the gel-forming region 2 of the base material 1. At this time, in the case where the gel-forming region 2 is hydrophilized in the surface treatment process, the first solution 3 remains in the gel-forming region 2 with good positional reproducibility to form a liquid pool in a predetermined region (FIG. 1 (b)).

The first solution 3 may be a solution containing an initiator, e.g., a photopolymerization initiator or thermal polymerization initiator, to absorb external energy and initiate polymerization of a gel-forming monomer described later and may be more favorably a water base solvent. For example, a mixed solution of a 1-M tris-hydrochloric acid buffer solution, TEMED, riboflavin (photopolymerization initiator), and pure water can be used. The amounts of them may be set appropriately in accordance with the concentration of the gel-forming monomer described later, and the mixing ratio is not specifically limited. In this regard, the first solution 3 can be fed to the base material 1 by using, for example, an ink-jet head, a pipetter, or a dispenser.

Meanwhile, as for the initiator besides the above-described riboflavin (photopolymerization initiator), photopolymerization initiators, such as, acetophenones, e.g., 2,2-dimethoxy-2-phenylacetophenone, and benzophenones, and thermal polymerization initiators, such as, benzoyl peroxide, and the like can be used. In this regard, the photopolymerization initiator refers to an initiator to initiate polymerization of the gel-forming monomer by stimulus of light, and the thermal polymerization inhibitor refers to an initiator to initiate polymerization of the gel-forming monomer by stimulus of heat.

In addition, it is favorable that the above-described initiator is uniformly dispersed in the first solution 3, and the above-described initiator is uniformly dispersed in the liquid pool formed on the gel-forming region 2. Consequently, the whole region of the liquid pool can gel uniformly in the polymerization initiation process described later. That is, in initiation of the polymerization of the gel-forming monomer, polymerization start points are uniformly dispersed in the liquid pool because the gel formation initiator is uniformly dispersed in the liquid pool. Consequently, gel formation uniformly occurs in the liquid pool. In this regard, the initiator is a reagent which does not become active spontaneously. For example, APS and TEMED which have been used previously are activated immediately in a solution state and, therefore, are not suitable for the initiator according to the present embodiment. As for the activation of the initiator according to the present embodiment, it is important that activation is initiated by at least one of externally applied energy, e.g., light, electricity, magnetism, and heat.

(Gradient Formation Process)

In the gradient formation process, a second solution 5 containing the gel-forming monomer is added to the first solution 3 to prepare a gel solution 6 provided with a pH gradient or gel-forming monomer concentration gradient. The gel-forming monomer is a monomer to become an electrophoresis gel 7 through polymerization. For example, an acrylamide mixed solution in which an acrylamide to form a main skeleton of the gel and N,N′-methylenebisacrylamide to cross-link the main skeleton of the gel are mixed, a mixed solution of the above-described acrylamide mixed solution and an acrylamide derivative (may be commercially available as Immobiline), and an agarose mixed solution adjusted to have a predetermined composition can be used as the second solution 5.

Examples of devices to add the second solution 5 include a pipetter, a dispenser, and an ink-jet head (ink-jet device). In particular, it is favorable that the ink-jet head be used, where fine droplets of the second solution 5 are ejected from a fine nozzle and are allowed to adhere to the base material 1. As shown in FIG. 1 (c), in the case where the second solution 5 can be ejected as fine droplets by using an ink-jet head 4, the gel concentration and the gel-forming region can be controlled easily.

Ejection devices by using the ink-jet head are roughly classified into a continuous ejection type (continuous ink jet) and an on-demand type (drop on-demand ink jet). Furthermore, examples of continuous ink jet include a charge control system in which charged fine droplets are controlled by an electric field. Examples of drop on-demand ink jet include a thermal (bubble) system, an electrostatic actuator system, and a piezoelectric system.

Also, for example, in the case where a pH gradient (IPG) gel is formed, a high-definition pH gradient can be formed by using the ink-jet head 4 and ejecting a low-pH acrylamide mixed solution and a high-pH acrylamide mixed solution while the mixing ratio is changed. Also, for example, a concentration gradient (gradient) gel is produced, a high-definition gray scale (gradient) can be formed by using the ink-jet head 4 and ejecting, for example, a 30% acrylamide mixed solution with a gradient. Consequently, a high-performance IPG gel or SDS-PAGE gradient gel can be provided.

In the case where fine droplets of the second solution 5 are ejected from the ink-jet head 4 while the liquid pool has been formed, as in the present embodiment, mutual mixing of the second solution 5 ejected into the liquid pool is facilitated to a great extent, so that gelation can be uniformly initiated in the whole region of the liquid pool. Therefore, degradation in the electrophoresis characteristics, which occurs in the case where a liquid pool is not present, can be prevented. Also, a higher-definition gradient can be formed, as necessary.

Meanwhile, in the case where these gels are produced, it is necessary that the pH or gel concentration be controlled sufficiently. In many cases, the gel-forming solution is ejected as fine droplets to the base material. Consequently, fine droplets of the gel-forming solution are favorably mixed with each other by improving the wettability because of the liquid pool formed on the surface of the base material. Also, a gel formation initiator is uniformly dispersed in the liquid pool, and the pH gradient or concentration gradient of the gel can be formed precisely by controlling the timing of activation of the gel-forming initiator, as described below.

(Polymerization Initiation Process)

Subsequently, a polymerization reaction of the gel solution 6 is initiated. In order to initiate the polymerization reaction, external energy, e.g., light, electricity, magnetism, or heat, is used in accordance with the initiator contained in the first solution 3. For example, in the case where riboflavin which is one of photopolymerization initiators is contained in the first solution 3, the gel solution 6 is irradiated with light (ultraviolet ray). Also, in the case where zenzoyl peroxide which is one of thermal polymerization initiators is contained in the first solution 3, the gel solution 6 is heated. Consequently, the gel solution 6 gels to become the electrophoresis gel 7. For example, in the case where the total amount of 140 microliters of gel solution 6 is prepared in the gel-forming region 2 having an area of 70 millimeters×1.2 millimeters, an electrophoresis reaction tool provided with 0.5 to 1.0 millimeters of electrophoresis gel 7 is obtained. In this regard, the thickness of the electrophoresis gel 7 is not specifically limited and can be, for example, on the order of several hundred millimeters to several millimeters. The resulting gel having this range of thickness is most suitable for the use in the electrophoresis experiment.

As described above, the gel polymerization reaction is initiated while the external energy, e.g., light or heat, serves as a trigger. Therefore, it is possible that the gel-forming monomer is diffused in the gel solution 6 for a predetermined time to form an appropriate pH gradient or concentration gradient and, thereafter, the gel is formed.

Meanwhile, favorably, the polymerization initiation process is performed in an atmosphere of, for example, an inert gas, e.g., argon, or nitrogen. That is, after the concentration gradient, the pH gradient, or the like is formed, it is desirable that the gel polymerization reaction is executed in the atmosphere of, for example, an inert gas, e.g., argon, or nitrogen because oxygen serving as an inhibitor of the gelation reaction is discharged from the inside of a reactor.

That is, in a conventional typical gelation reaction, gel is cast to a gel producing jig formed from a glass substrate or the like, so that exposure to the air does not occur easily. However, the electrophoresis reaction tool according to the present embodiment stores the gel solution 6 on the base material 1 directly. Therefore, most of the surface of the gel solution 6 is exposed to the air and is influenced by oxygen easily. Consequently, it is desirable that the inside of the reactor is brought into an inert gas or nitrogen atmosphere.

Here, in the present embodiment, the process to form the concentration gradient or pH gradient from the gel-forming solution and the process to form the gel are separated. Therefore, the gel can be formed in a place different from a place of gradient formation of the gel-forming solution, so that large effects are exerted from the viewpoint of simplification of the apparatus and an improvement in the production efficiency. Also, a problem that gelation occurs unnecessarily in the gel producing jig or the gel producing apparatus can be prevented completely.

As described above, according to the method for manufacturing an electrophoresis reaction tool of the present embodiment, the individual solutions to form the gel are ejected to the gel-forming region 2 formed at an arbitrary position on the base material 1 and, thereby, the gel 7 having arbitrary size, composition, and concentration can be directly formed with high positional reproducibility. Also, high-definition gradient formation and prevention of troubles of apparatus can be achieved by performing gradient formation of the gel and gel formation in separate processes.

Therefore, according to the method for manufacturing an electrophoresis reaction tool of the present embodiment, the gel can be formed at an arbitrary position, for example, on an end surface of the base material 1, whereas the place of formation of the gel has been restricted in the past because a casting jig formed from a glass substrate or the like has been used.

In addition, the gel formation initiator is disposed in the first gel-forming solution and, thereby, an occurrence of unnecessary gelation in the gel producing jig or the gel producing apparatus (reaction tool producing apparatus) can be prevented. In this regard, the amount of ejection per scan of the gel-forming solution ejected from the ink-jet head is about 1 μL (20 to 40 μL/droplet), and the number of scans increases to increase the film thickness. Consequently, a gel solution ejected at an early stage may gel before all gel solution is ejected, so that it is difficult to form a gel having good quality.

Then, gel formation can be controlled by diffusing the polymerization initiator into the liquid pool in advance and activating at a predetermined timing. Therefore, an occurrence of inconvenience of apparatus, such as, plugging of pipe due to proceeding of an unnecessary gelation reaction, can be prevented and a homogeneous gel can be produced.

(Producing Apparatus)

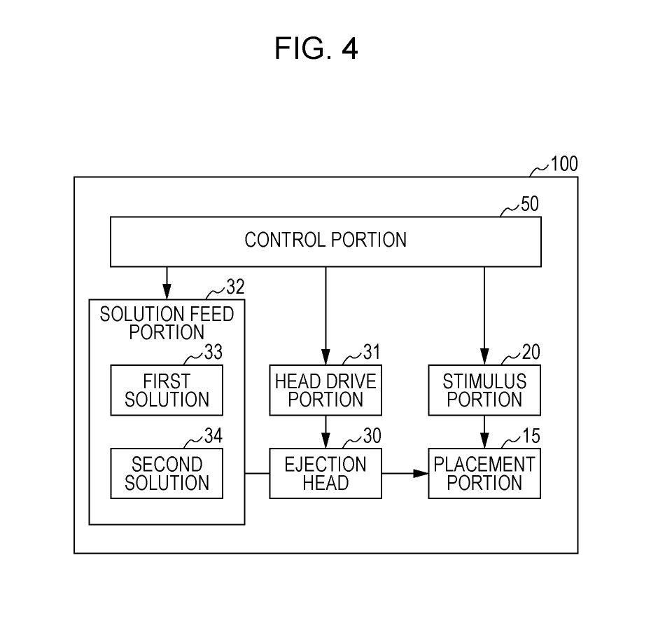

In an aspect, the method for manufacturing an electrophoresis gel according to the present embodiment may be executed by a producing apparatus 100 shown in FIG. 4.

The producing apparatus 100 is provided with a placement portion 15 to place the base material 1, a stimulus portion 20 to apply external energy to the base material 1 of the placement portion 15, an ejection head (gradient-forming device) 30 to eject the first solution 3 and the second solution 5 to the base material 1 of the placement portion 15, a head drive portion 31 to drive the ejection head 30, a solution feed portion 32 to feed the first solution 3 and the second solution 5 to the ejection head 30, and a control portion 50 to control the stimulus portion (polymerization initiation device) 20, the head drive portion 31, and the solution feed portion 32. The solution feed portion 32 is provided with a first solution storing portion 33 to store the first solution 3 and at least one second solution storing portion 34 to store at least one type of second solution 5 on one-to-one basis. Also, the ejection head 30 may be an ink-jet head (ink-jet device).

Then, the control portion 50 executes the first solution storing process by controlling the solution feed portion 32 to feed the first solution 3 to the ejection head 30 and, in addition, controlling the head drive portion 31. Subsequently, the control portion 50 executes the gradient-forming process by controlling the solution feed portion 32 to feed the second solution 5 to the ejection head 30 and, in addition, controlling the head drive portion 31. Finally, the control portion 50 initiate the gel polymerization by controlling the stimulus portion 20 to apply the external energy to the gel solution 6. In this regard, in the case where the initiator contained in the first solution 3 is a photopolymerization initiator, the stimulus portion 20 may be a light (ultraviolet ray) irradiation apparatus, and in the case where the initiator contained in the first solution 3 is a thermal polymerization initiator, the stimulus portion 20 may be a heating apparatus.

### Configuration Example 1

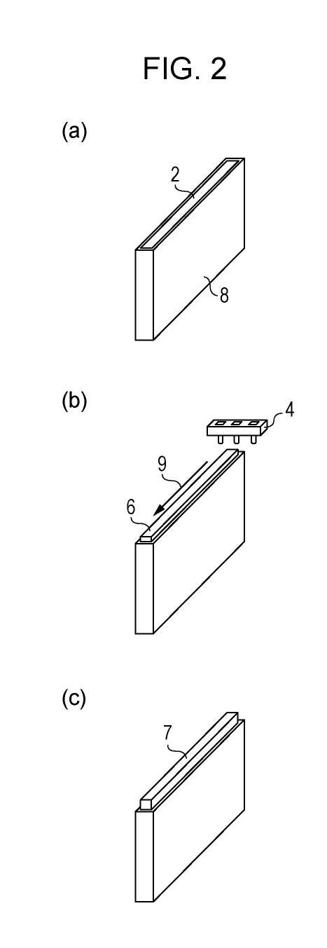

Here, an example of the present embodiment will be described with reference to FIG. 2. FIG. 2 shows diagrams illustrating an example of a method for manufacturing a first-dimension gel (immobilized pH gradient gel, IPG gel) in the two-dimensional electrophoresis method.

As shown in FIG. 2, in the present configuration example, an electrophoresis gel 7 is immobilized to a tabular base material 8. The tabular base material 8 includes a gel-forming region 2 on at least part of the surface, to which the gel 7 is immobilized, where the gel-forming region 2 has been subjected to a treatment for adhesion of the electrophoresis gel 7.

Initially, as shown in FIG. 2 (a), the gel-forming region 2 is formed on the upper end surface of the tabular base material 8. For example, a plastic substrate of polymethyl methacrylate resin (PMMA) or the like or a glass substrate can be used as the tabular base material 8.

The gel-forming region 2 in the shape of a frame is disposed in the vicinity of the outer region of the upper surface of the tabular base material 8. For example, the hydrophobic surface of the tabular base material 8 is subjected to a hydrophilic surface treatment by glow discharge, arc discharge, or the like and a deposition treatment of insulating fine particles (fine particle diameter; several nanometers to several hundred nanometers) of silicon oxide or the like. A liquid pool can be formed in a predetermined region and the region to be provided with the electrophoresis gel 7 can be controlled easily by disposing such a gel-forming region 2 on the tabular base material 8.

However, the configuration of the gel-forming region 2 is not limited to this and may be, for example, a region subjected to water-soluble polymer coating, agarose derivative coating, a nanoimprinting treatment, a plasma graft polymerization film treatment, or the like on the upper surface of the tabular base material 8.

In addition, the gel-forming region 2 of the tabular base material 8 can be provided with concave structures having a depth of several micrometers to several hundred micrometers (mortise structure) or convex structures (protuberance structure). Also, the above-described configurations can be combined.

Next, the first solution 3 is stored on the gel-forming region 2 and, thereafter, the gel solution 6 is prepared (FIG. 2 (b)). Examples of devices to feed the first solution 3 on the gel-forming region 2 include a pipetter, a dispenser, and an ink-jet head.

The first solution 3 (for example, riboflavin is included as a photopolymerization initiator) is stored on the gel-forming region 2 and, thereafter, the gel solution 6 provided with a pH gradient is prepared by adding the second solution 5 to the gel-forming region 2 provided with the liquid pool of the first solution 3. Examples of the second solution 5 include an acrylamide derivative mixed solution. As for a reagent to form an IPG gel, for example, an acrylamide derivative mixed solution having various acid dissociation constants, an isoelectric focusing reagent, a photopolymerization initiator, and pure water are mentioned as an example. The acrylamide derivative mixed solution is a solution in which, for example, two types of acrylamide derivatives different in pH are mixed, and an acrylamide derivative mixed solution having predetermined pH is obtained by mixing acrylamide derivatives having various dissociation constants through the use of acrylamide derivatives having positive charges or negative charges. Meanwhile, the isoelectric focusing reagent (Ampholine) is an amphoteric electrolyte mixture. The isoelectric focusing reagent is not necessarily contained in the second solution 5.

An ink-jet head 4 suitable for forming a pH gradient can be used as the device to add the second solution 5. For example, as shown in FIG. 2 (b), in order that pH gradients of two types of acrylamide derivative mixed solutions can be formed in the gel-forming region 2 storing the first solution 3, the ink-jet head 4 is scanned in the longitudinal direction (ink-jet scanning direction 9) of the tabular base material 8.

For example, one acrylamide derivative mixed solution of the two types of acrylamide derivative mixed solutions is adjusted to have pH 3, the other acrylamide derivative mixed solution is adjusted to have pH 10, and the resulting acrylamide derivative mixed solutions are ejected as fine droplets from the ink-jet head 4. In this regard, the explanation of a method for adjusting the acrylamide derivative mixed solution is omitted because a common method may be used.

Meanwhile, in the gel solution 6 (FIG. 2 (b)) containing the acrylamide derivatives formed by ejecting the acrylamide derivative mixed solutions from the ink-jet head 4 to the gel-forming region 2, the initiator is not activated and, therefore, the gelation reaction does not occur until the following process, so that the solution state remains.

Subsequently, the gel polymerization reaction is initiated by applying the external energy to the gel solution 6 provided with the pH gradient. In the present embodiment, the photopolymerization initiator is used as the initiator. Therefore, light (for example, ultraviolet ray) is applied to initiate the gel polymerization reaction (FIG. 2 (c)).

In this manner, an IPG gel (electrophoresis gel 7) having a pH of 3 to 10 and the size of the IPG gel of 52 nm (isoelectric focusing gradient direction)×1.2 mm×0.5 mm, for example, and an electrophoresis reaction tool in which the above-described IPG gel is immobilized to the tabular base material 8 with good positional precision can be obtained.

### Configuration example 2

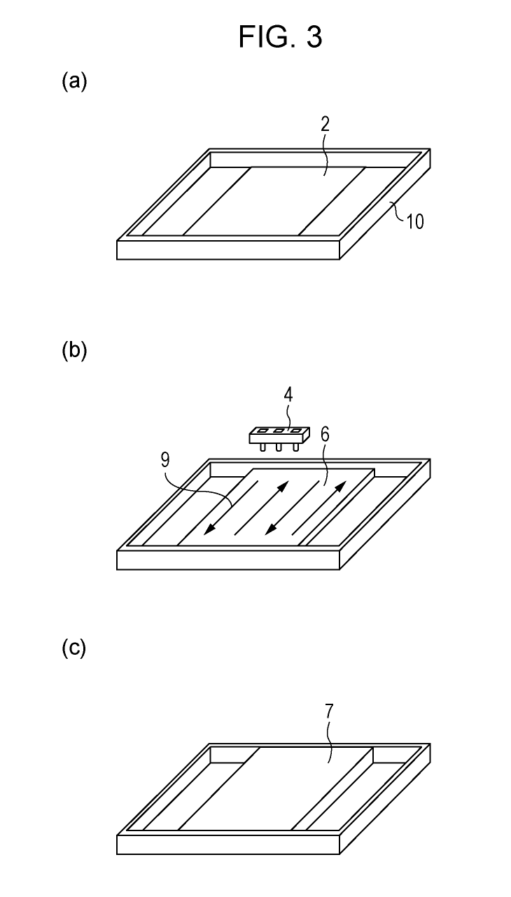

Next, another example according to the present embodiment will be described with reference to FIG. 3. FIG. 3 shows diagrams illustrating an example of production of a second-dimension gel (SDS-PAGE gel, gradient gel) in the two-dimensional electrophoresis method.

In this regard, in the method for manufacturing an electrophoresis gel used for generally known SDS-PAGE gel electrophoresis, a polyacrylamide gel is cast to the base material and the like formed from a plastic resin, e.g., PMMA. However, in the method for manufacturing an electrophoresis gel, according to the present embodiment, as with Configuration example 1, it is not necessary that the base material be provided with a casting structure, and the base material may have a structure of a plastic flat plate, a glass flat plate, or the like. Meanwhile, the concentration gradient (gradient) gel can be favorably used as, for example, a gradient gel applied to the second medium (2D gel) and the second separation portion (sample tool) disclosed in Japanese Unexamined Patent Application Publication No. 2007-64848 (published on Mar. 15, 2007).

A reagent to form the gradient gel may contain, for example, the same solutions as those in the above-described polyacrylamide gel.

Initially, as shown in FIG. 3 (a), a gel-forming region 2 is formed in a predetermined region of a try base material 10 to be provided with a gradient gel. For example, a plastic substrate of PMMA or the like or a glass substrate can be used as the tray base material 10.

Also, in the present configuration example, it is suitable that the gel-forming region 2 of the tray base material 10 is specified to be hydrophilic, formation of nanosized concavities and convexities is favorably performed, and the region other than the gel-forming region 2 is specified to be hydrophobic. For example, the gel-forming region 2 can be formed by masking the region other than the gel-forming region 2 of the tray base material 10 and performing a hydrophilic treatment, e.g., an oxygen plasma treatment, a sulfonation treatment, or a nitration treatment, and formation of fine concave and convex structures, e.g., a chemical vapor deposition method, in combination.

Subsequently, a gradient is formed on the tray base material 10. Initially, a first solution 3 is stored on the gel-forming region 2 of the tray base material 10. For example, a 1-M tris-hydrochloric acid buffer solution, riboflavin, and pure water are mentioned as the first solution 3. The mixing ratio of them is not specifically limited. Examples of devices to eject the first solution 3 include a pipetter, a dispenser, and an ink-jet head.

After the first solution 3 is stored, a gradient is formed by adding a second solution 5 to the gel-forming region 2 provided with the liquid pool while, for example, the amount is changed. Examples of the second solution 5 include an acrylamide mixed solution (acrylamide+N,N′-methylenebisacrylamide). The concentration of the acrylamide mixed solution can be a relatively high concentration of, for example, 30% to 50% (acrylamide:N,N′-methylenebisacrylamide=37.5:1).

Examples of devices to eject the second solution 5 include a pipetter, a dispenser, and an ink-jet head. For example, the ink-jet head 4 is used and is scanned along the direction indicated by arrows showing the ink-jet scanning direction 9, so that a high-definition gradient can be formed favorably. Also, a large-size SDS-PAGE gel can be formed by forming a gradient with a static mixer or a gradient mixer and, thereafter, performing ejection by using a dispenser.

In this regard, in the gel solution 6 (FIG. 3 (b)) containing the acrylamide mixture, riboflavin serving as a photopolymerization initiator is not activated and, therefore, the gelation reaction does not occur until the following process, so that the solution state remains.

Subsequently, the gel polymerization reaction is initiated by applying the external energy to the gel solution 6 provided with the gradient. In the present embodiment, the photopolymerization initiator is used as the initiator. Therefore, ultraviolet ray irradiation is performed to initiate the gel polymerization reaction (FIG. 3 (c)).

As with Configuration example 1, riboflavin uniformly dispersed in the liquid pool initiates the gel polymerization reaction at the same time in the gel solution 6, so that a high-quality SDS-PAGE gel can be formed.

For example, an electrophoresis reaction tool can be produced, wherein a SDS-PAGE gel (electrophoresis gel 7), in which the low concentration side is 4%, the high concentration side is 15%, and the gradient gel size is 50 nm (concentration gradient direction)×60 mm×1 mm, is disposed on the tray base material 10.

In this regard, after the gradient of the acrylamide monomer shown in FIG. 3 (b) is formed, a gel can be formed by performing ultraviolet ray irradiation in an atmosphere of an inert gas, e.g., nitrogen or argon, although the gel-forming environment is not limited to this.

The present disclosure is not limited to the above-described embodiments, various modifications can be made within the scope shown in the claims, and embodiments obtained by appropriate combinations of the individually disclosed technical devices are included in the technical scope of the present disclosure. Also, the entire contents of all literatures described in the present specifications are hereby incorporated by reference.

### Second Embodiment

<Method for Manufacturing Electrophoresis Reaction Tool>

A method for manufacturing an electrophoresis reaction tool, according to the present disclosure, includes an application process to apply a mixed material of a monomer to form a gel and a photoresist material to a base material, a gelation process to apply external energy to a predetermined region of the above-described mixed material applied to the above-described base material and, thereby, allow the above-described monomer in the region irradiated with the external energy to gel, and a removal process to develop the above-described mixed material after the above-described gelation process and remove the above-described mixed material in the region not irradiated with the external energy.

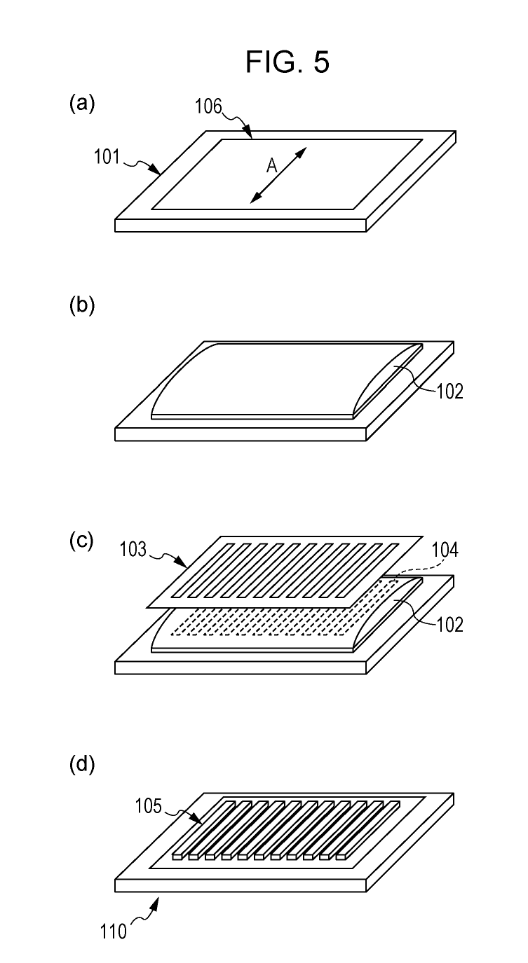

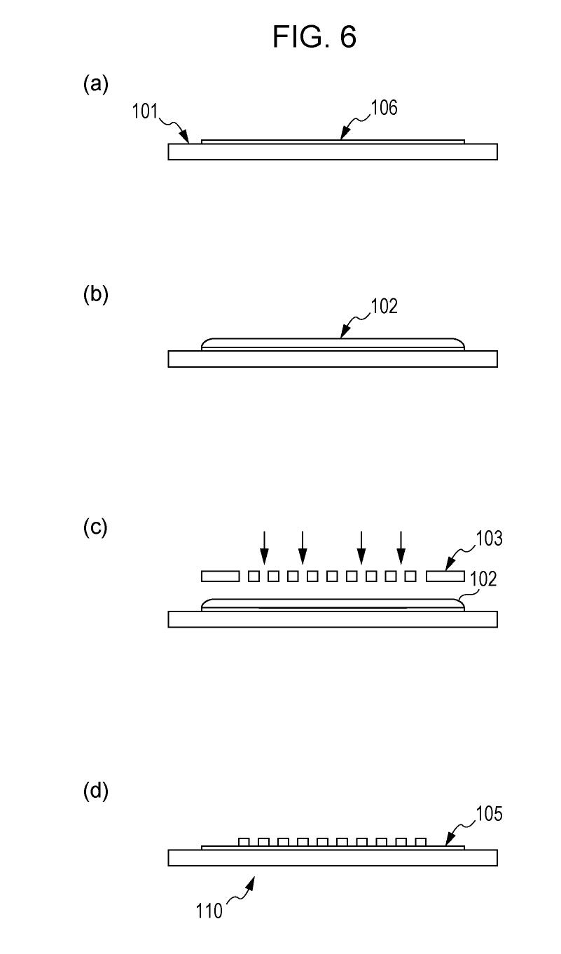

The embodiment of the manufacturing method according to the present disclosure will be described below in detail with reference to FIG. 5 and FIG. 6. FIG. 5 shows perspective views illustrating the production processes of an electrophoresis reaction tool according to an embodiment of the present disclosure. FIG. 6 shows sectional views illustrating the production processes of an electrophoresis reaction tool according to an embodiment of the present disclosure.

Electrophoresis is a method for separating biopolymers, e.g., proteins, DNA, and RNA, in a sample into the individual biopolymers through the use of the difference in transfer rate of the biopolymers in a predetermined electric field due to the difference in size or charge. Examples of types of electrophoresis include polyacrylamide gel electrophoresis by using a polyacrylamide gel as a support and agarose gel electrophoresis by using an agarose gel as a support. In the case where biopolymers in a sample are separated by electrophoresis, a voltage is applied to the biopolymers in the sample and, thereby, the biopolymers are transferred in the support.

(Electrophoresis Reaction Tool 110)

As shown in FIG. 5 (d) and FIG. 6 (d), an electrophoresis reaction tool 110 according to the present embodiment is a tool in which a plurality of gels 105 are immobilized on a base material 101.

The electrophoresis reaction tool 110 is used for inducing one-dimensional electrophoresis or two-dimensional electrophoresis. Furthermore, the electrophoresis reaction tool 110 can be favorably used as a first-dimension electrophoresis reaction tool to separate biopolymers in a sample by isoelectric focusing (IEF) or a second-dimension electrophoresis reaction tool to separate biopolymers in a sample by sodium dodecyl sulfate-polyacrylamidegel electrophoresis (SDS-PAGE).

(Sample)

As for the sample to be separated by electrophoresis, preparations taken from, for example, biological materials, e.g., biological individuals, body fluids, cell lines, tissue culture materials, and tissue pieces, can be favorably used. In particular, proteins, polypeptides, and polynucleotides are used favorably.

(Base Material 101)

The base material 101 supports and immobilizes the gels 105. Examples of base material 101 include a flat plate and a chip formed into a predetermined shape. The base material 101 is not limited to the flat plate or the like insofar as the gels are supported and immobilized and may be a housing or the like to store the gels.

Examples of materials for forming the base material 101 include glass, plastic, and ceramic. Examples of glass include quartz glass and alkali-free glass. Examples of plastic include polyethylene terephthalate (PET), polymethyl methacrylate (PMMA), and polycarbonate (PC). Examples of ceramic include alumina (Al₂O₃), zirconia oxide (ZrO₂), aluminum nitride (AlN), silicon carbide (SiC), and low temperature co-fired ceramic.

(Monomer)

The monomer used in the present embodiment is a monomer to form a gel and examples include acrylamides and agarose which gel by polymerization or cross linking. Also, the monomers may contain cross-linking agents, e.g., N,N′-methylenebisacrylamide, acrylamide derivatives (derivatives in which predetermined substituents are introduced into acrylamides for the purpose of giving various acid dissociation constants), and the like.

(Photoresist Material)

The properties, e.g., solubility in a developing solution, of the photoresist material are changed by application of the external energy, e.g., light energy or electron beam energy.

As for the photoresist material, a negative type in which a region irradiated with the external energy remains after development or a positive type in which a region irradiated with the external energy is removed through development can be used. In the present embodiment, the case where the photoresist material is the negative type will be described as an example.

(Mixed Material 102)

The mixed material 102 is a mixture of the monomer and the photoresist material. In order to spread the mixed material 102 on the gel-forming region 106 of the base material 101, the mixed material 102 in which the monomer and the photoresist material are mixed in advance may be applied to the gel-forming region 106 of the base material 101 or the monomer and the photoresist material may be applied to the base material 101 separately. It is favorable that the photoresist material is uniformly dispersed in the mixed material 102.

(Radical Polymerization Initiator and Thickener)

The mixed material 102 may contain a radical polymerization initiator and a thickener besides the monomer and the photoresist material. The order of addition of the radical polymerization initiator and the thickener to the mixed material 102 is not specifically limited. For example, they may be applied to the base material 101 before the mixed material 102 is applied to the base material 101 or be added to the mixed material 102 spread on the base material 101.

The radical polymerization initiator is activated by being irradiated with the external energy and generate radicals to initiate radical polymerization of the monomer in the mixed material 102. The radical polymerization initiator is composed of, for example, a photosensitizer or an electron sensitizer and a peroxide.

Examples of photosensitizers and electron sensitizers include riboflavin, benzophenones, and acetophenones. Examples of peroxides include ammonium persulfate and hydrogen peroxide.

These photosensitizer or electron sensitizer and peroxide are mixed at a predetermined composition and, thereby, a radical polymerization initiator is prepared. The radical polymerization initiator added to the mixed material 102 is favorably about 0.3% to about 5.0% of the total weight of the monomer and the cross-linking agent. In order to allow the monomer to uniformly gel in the mixed material 102, it is favorable that the radical polymerization initiator be uniformly dispersed in the mixed material 102.

The thickener is added to the mixed material 102 and, thereby, increases the viscosity thereof and suppresses diffusion of the monomer in the mixed material 102. Examples of thickeners include polyol compounds, e.g., glycerol, polyethylene glycol, and polyvinyl alcohol, and saccharide. The thickener added to the mixed material 102 is favorably about 1% to about 40% of the mass of mixed material 102.

In the case where the thickener is added to the mixed material 102, the radical polymerization initiator can be dispersed in the high-viscosity mixed material 102, and only a predetermined region of the mixed material 102 can gel accurately by being irradiated with the external energy.

In this regard, it is favorable that the above-described radical polymerization initiator, which generates radicals by being irradiated with the external energy, be added to the mixed material 102. However, it is not favorable that a radical polymerization initiator, which is activated spontaneously and generates radicals, be added to the mixed material 102. For example, APS or TEMED, which has been previously frequently used as the radical polymerization initiator, is not favorable as the radical polymerization initiator according to the present embodiment because activation is immediately induced in a solution state and radicals are generated.

(External Energy)

Examples of external energy applied to the mixed material 102 include light energy and electron beam energy, as described above. Examples of irradiation devices to apply the light energy or electron beam energy to the mixed material 102 include semiconductor lasers (wavelength 830 nm, 532 nm, 488 nm, 405 nm, or the like), metal halide lamps, high pressure mercury vapor lamps (wavelength 436 nm, wavelength 405 nm, wavelength 365 nm), excimer lasers (wavelength 248 nm, wavelength 193 nm, wavelength 157 nm), extreme ultraviolet irradiation apparatus (13.6 nm), and electron beam irradiation apparatus. The above-described irradiation device is selected appropriately in accordance with the properties of the photoresist material or radical polymerization initiator.

(Surface Treatment)

As shown in FIG. 5 (a) and FIG. 6 (a), the base material 101 may be subjected to a surface treatment to prepare a gel-forming region 106, where the gel is formed on the surface treated region. The surface treatment is performed to feed the mixed material 102 of the monomer and the photoresist material to a predetermined region of the base material 101 and allow the gels 105 to adhere to the predetermined region.

The gel-forming region 106 is a region having improved wettability with the mixed material 102 and improved adhesion to the gels 105 and suppresses peeling of the gels 105. Also, the gel-forming region 106 functions as a liquid pool (droplet supplementation region) of the mixed material 102, and part of this droplet supplementation region can be a predetermined region to which the gels 105 are allowed to adhere.

Examples of surface treatments include dry process treatments, e.g., an oxygen plasma treatment and plasma graft polymerization film formation, wet process treatments, e.g., a hydrophilic polymer coating treatment, a nitration treatment, a sulfonation treatment, and washing with a mixed acid solution of sulfuric acid and hydrogen peroxide, fine shape (concave and convex shape of several nanometers to several tens of nanometers) formation treatments, e.g., a nanoimprinting treatment, a microdot treatment, a nanodot treatment, a graft polymer coating treatment, and insulating fine particle deposition, and combinations thereof. Furthermore, as for the surface treatment, for example, a fine shape formation treatment by deposition of insulating fine particles made from silicon oxide or the like having a diameter of several nanometers to several tens of nanometers and a combination of the fine shape formation treatment by the above-described insulating fine particle deposition and a hydrophilic surface treatment by oxygen plasma or the like are favorable. As described above, the adhesion of 105 to the base material 101 can be improved.

In the case where the predetermined region of the base material 101 is surface-treated, the base material 101 may be surface-treated after the portion other than the region concerned is masked.

[Coating Process]

In the method for manufacturing an electrophoresis reaction tool, according to the present disclosure, initially, in a coating process, the mixed material 102 of the monomer to form the gels 105 and the photoresist material is applied to the base material 101. That is, as shown in FIG. 5 (a), an ink-jet head (not shown in the drawing) is scanned in the direction indicated by an arrow A, and as shown in FIG. 6 (b), the monomer and the photoresist material are applied to the gel-forming region 106 of the base material 101, and the mixed material 102 of the monomer and the photoresist material is spread on the gel-forming region 106.

Examples of coating devices to apply the monomer and the photoresist material include a pipetter, a dispenser, and an ink-jet head (ink-jet ejection device).

In this regard, as for the ink-jet head, a continuous ejection type (continuous ink jet), an on-demand type (drop on-demand ink jet), and the like can be used favorably. Examples of continuous ink jet include a charge control system in which charged fine droplets are controlled by an electric field. Examples of drop on-demand ink jet include a thermal (bubble) system, an electrostatic actuator system, and a piezoelectric system. The diameter of a droplet particle ejected by the ink-jet head can be controlled by the viscosities and the surface tensions of the monomer and the photoresist material, the voltage applied to the ink-jet head, and the like.

Coating of the gel-forming region 106 with the monomer and the photoresist material may be performed by spray coating, spin coating, and the like, although ejection from the ink-jet head is favorable, as described above. Also, the monomer and the photoresist material may be ejected from separate ink-jet heads, or they may be mixed in advance and be ejected from one ink-jet head while being in the state of a mixed material.

The amount of application of the monomer and the photoresist material to the gel-forming region 106 may be, for example, such an extent that a thin film of the liquid can be formed on the gel-forming region 106, and the amount can be set appropriately in accordance with the thickness and the like of the gel to be formed.

In the case where the gel obtained by gelation of the monomer is a gel having a monomer concentration gradient (gradient gel in SDS-PAGE) or a gel having a pH gradient (IPG gel in IEF), it is favorable that the monomer and the photoresist material be ejected to the gel-forming region 106 by using the ink-jet device. Also, in the case where the gradient or the like is formed, it is favorable that a process to eject the photoresist material and a process to form a concentration gradient or pH gradient in the gel-forming monomer be performed in two steps.

Also, in the case where a gradient gel or IPG gel (immobilized pH gradient gel) is formed on the base material 101, it is favorable that a radical polymerization initiator prepared by mixing a sensitizer and a peroxide be applied to the gel-forming region 106 of the base material 101 and, thereafter, the monomer and the photoresist material having a monomer concentration gradient or a pH gradient be ejected to the gel-forming region 2.

Examples of methods for forming a pH gradient in the mixed material 102 to form the IPG gel include a method in which acrylamide derivatives (commercially available reagents, e.g., Immobiline and an acrylamide buffer) including specific substituents (for example, a carboxyl group and an amino group) and having different dissociation constant (pK) values are dispersed in the monomer solution or the mixed material 102. That is, acrylamide derivative solutions having a pH serving as the start point of the pH gradient (for example, pH 3) and a pH serving as the end point (for example, pH 10) are prepared, these solutions are mixed by using a mixing device, e.g., a gradient mixer or a static mixer, while the mixing ratio is changed and, thereby, the monomer solution or the mixed material 102 having an arbitrary pH gradient can be prepared.

Examples of methods for forming a monomer concentration gradient in the mixed material 102 to form the gradient gel include a method in which a high-concentration acrylamide solution (10% to 20%) and a low-concentration acrylamide solution (5% to 10%) are mixed in the monomer solution or the mixed material 102. That is, these solutions are mixed by using a mixing device, e.g., a gradient mixer or a static mixer, while the mixing ratio is changed and, thereby, the monomer solution or the mixed material 102 having an arbitrary monomer (acrylamide) concentration gradient can be prepared.

Meanwhile, it is also possible to form the pH gradient or monomer concentration gradient in the mixed material 102 by changing the density of a droplet ejected by the ink jet.

[Gelation Process]

In the gelation process, the external energy is applied to a predetermined region of the mixed material 102 applied to the base material 101 and, thereby, the monomer in the region irradiated with the external energy is allowed to gel. In the gelation process, as shown in FIG. 5 (c) and FIG. 6 (c), the external energy applied from an irradiation device through a photomask (shielding film) 103 may be applied to a predetermined gelation region 104 of the mixed material 102. In the gelation process, gelation of the monomer proceeds in the gelation region 104 irradiated with the external energy, although in the region other than the gelation region 104 (region shielded from the radiation energy by the mask), the monomer does not gel and is present in a solution state.

The photomask 103 is used by being placed on the mixed material 102 and prevents application of the external energy to the region other than the gelation region 104 of the mixed material 102.

The gelation region 104 is a region irradiated with the external energy in the mixed material 102 spread on the gel-forming region 106 and is a region in which gelation of the monomer proceeds. Therefore, the photomask 103 may be formed in such a way that the region other than the gelation region 104 in the mixed material 102 is covered with the photomask 103. Consequently, in the mixed material 102, the region irradiated with the external energy and the region in which gelation of the monomer proceeds can be determined in accordance with the shape of the photomask 103.

The photomask 103 can be produced into a predetermined shape by using, for example, a glass dry plate (photomask in which a chromium layer or a chromium oxide layer is patterned on a glass or quartz substrate) used in a semiconductor production process or a metal plate.

In this regard, a direct writing method in which the external energy is directly applied to the mixed material 102 may be adopted without placing the photomask 103 between an irradiation source 107 and the mixed material 102.

[Removal Process]

In the removal process, the mixed material 102 after the gelation process is developed, and the mixed material 102 in the region not irradiated with the external energy is removed. Consequently, as shown in FIG. 5 (d) and FIG. 6 (d), the gels 105 having the predetermined shape can be formed on the base material 101.

The removal process according to the present embodiment can be performed in the same manner as that in the development process in the photolithography process of the semiconductor production process. As for the removal process, a process in which the mixed material 102 after the gelation process is immersed in a developing solution, e.g., pure water, an acetic acid-sodium acetate buffer solution (adjusted to about pH 7), or the like, and shaking is performed for about 10 to 60 minutes is mentioned. Consequently, the mixed material 102 in the region not irradiated with the external energy is dissolved into the developing solution, and is removed from the base material 101 easily. Meanwhile, the mixed material 102 in the region irradiated with the external energy is not dissolved into the developing solution, and only gels 105 remain on the base material 101.

As described above, the mixed material 102 containing the monomer and the photoresist material is used as the material for forming the gel, so that the gels 105 can be formed in only the predetermined region and the mixed material 102 in the region which has not gelled can be removed easily by performing development after the predetermined region is irradiated with the external energy. As a result, the gel having the predetermined shape can be formed easily, so that the production efficiency of the electrophoresis reaction tool 110 can be improved and the production processes can be simplified.

As described above, in the method for manufacturing an electrophoresis reaction tool, according to the present embodiment, for example, a mixture of an IPG gel-forming monomer prepared from an acrylamide (main skeleton), a bisacrylamide (cross-linking agent), and an acrylamide derivative at a predetermined mixing ratio, a photoresist material, a radical polymerization initiator formed from riboflavin and ammonium persulfate, and glycerol serving as a thickener can be favorably used as the mixed material 102.

Then, the mixed material 102 mixed as described above is applied to the base material 101, the external energy is applied through the photomask 103 and, thereby, the IPG gel-forming monomer in the region irradiated with the external energy is allowed to gel. After the external energy is applied, the mixed material 102 is developed by washing with pure water and, thereby, the gels 105 patterned into the shape corresponding to the shape of the photomask 103 can be formed on the base material 101.

In the method for manufacturing an electrophoresis reaction tool, according to the present embodiment, the shape of the gels 105 formed on the base material 101 can be controlled by design of the photomask 103. That is, the shape of the gels 105 corresponds to the shape of the photomask 103. Meanwhile, the film thickness of the resulting gels 105 can be controlled by adjusting the amount of application of the mixed material 102 to the base material 101. That is, the gels 105 having a predetermined film thickness can be formed by adjusting the amount of application of the mixed material 102 to the base material 101. One example of the resulting gels 105 is 70 mm long×3 mm wide×0.5 mm thick and the space between the gels 105 is 3 mm.

<Apparatus for Manufacturing Electrophoresis Reaction Tool>

An apparatus for manufacturing an electrophoresis reaction tool, according to the present disclosure, includes at least a coating device to apply a mixed material of a monomer to form a gel and a photoresist material to a base material, an irradiation device to apply external energy to a predetermined region of the above-described mixed material applied to the above-described base material, so as to allow the above-described monomer in the region irradiated with the external energy to gel, and a development device to develop the above-described mixed material after being irradiated with the external energy and remove the above-described mixed material in the region not irradiated with the external energy. The above-described manufacturing apparatus may further includes the above-described shielding film. In this regard, each device of the apparatus for manufacturing an electrophoresis reaction tool, according to the present disclosure, is one embodiment of the device used for executing each process of the above-described method for manufacturing an electrophoresis reaction tool, according to the present disclosure. Therefore, one embodiment of the apparatus for manufacturing an electrophoresis reaction tool, according to the present disclosure, is in conformity with the explanations of the above-described method for manufacturing an electrophoresis reaction tool, according to the present disclosure, and detailed explanations thereof will not be provided.

[Coating Device]

The coating device is not limited insofar as the monomer to form the gel and the photoresist material are applied to the base material and, for example, the above-described dispenser, ink-jet head (ink-jet ejection device), or the like is mentioned. Also, the apparatus for manufacturing an electrophoresis reaction tool may include a mixing device, e.g., a gradient mixer or a static mixer, in order to form a gradient gel or IPG gel on the base material.

[Irradiation Device]

Examples of irradiation devices include those which apply the external energy, e.g., light energy or electron beam energy, to the mixed material of the monomer and the photoresist material. Therefore, examples of irradiation devices include semiconductor lasers (wavelength 830 nm, 532 nm, 488 nm, 405 nm, or the like), metal halide lamps, high pressure mercury vapor lamps (wavelength 436 nm, wavelength 405 nm, wavelength 365 nm), excimer lasers (wavelength 248 nm, wavelength 193 nm, wavelength 157 nm), extreme ultraviolet irradiation apparatus (13.6 nm), and electron beam irradiation apparatus.

[Development Device]

The development device develops the mixed material irradiated with the external energy and removes the mixed material in the region not irradiated with the external energy. Also, the development device according to the present embodiment can have the same configuration as that of the development device in the photolithography process in the semiconductor production process. Therefore, examples of development devices include a device which immerses a developing solution, e.g., pure water, an acetic acid-sodium acetate buffer solution (adjusted to about pH 7), or the like, in the mixed material and performs shaking.

The gel having the predetermined shape can be formed easily by using the apparatus for manufacturing an electrophoresis reaction tool, according to the present embodiment, so that the production efficiency of the electrophoresis reaction tool can be improved and the production processes can be simplified.

<Electrophoresis Gel Material>

An electrophoresis gel material containing the monomer to form the gel and the photoresist material, wherein the electrophoresis gel material is to form a gel having the predetermined shape by allowing only the region irradiated with the external energy to gel and removing the region not irradiated with the external energy through development, is also included in the scope of the present disclosure.

As for the electrophoresis gel material, it is possible to allow only the region irradiated with the external energy to gel and remove the region not irradiated with the external energy through development. Consequently, the gel having the predetermined shape can be formed on the above-described base material, a substrate, or the like by using the electrophoresis gel material.

### Third Embodiment

<Method for Manufacturing Electrophoresis Reaction Tool>

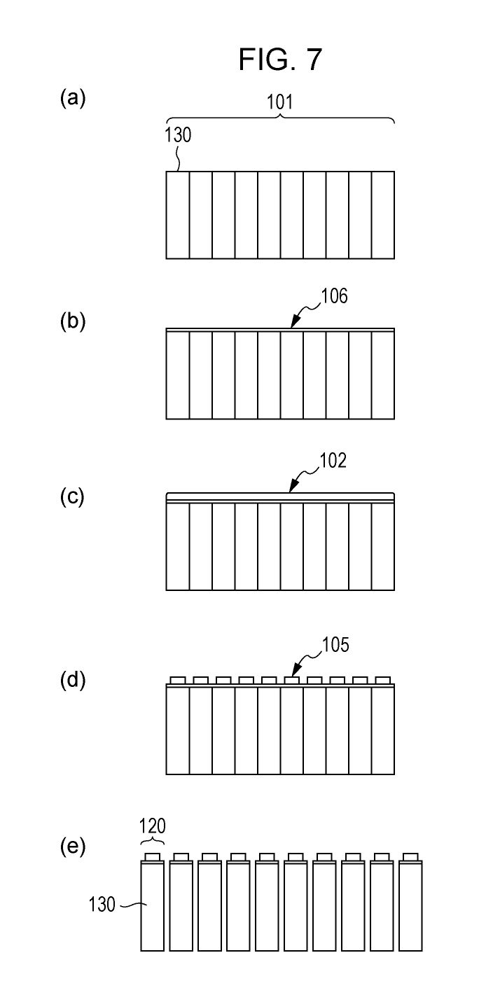

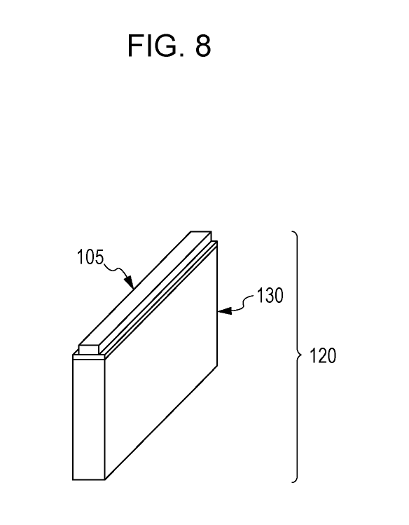

Another embodiment of the method for manufacturing an electrophoresis reaction tool, according to the present disclosure, will be described below with reference to FIG. 7 and FIG. 8. FIG. 7 shows diagrams illustrating the production processes of a plurality of electrophoresis reaction tools, according to another embodiment of the present disclosure. FIG. 8 is a perspective view illustrating an electrophoresis reaction tool according to another embodiment of the present disclosure.

The present embodiment is different from the method for manufacturing the electrophoresis reaction tool 110 explained in the second embodiment in the point that a plurality of base materials 101 are connected and are treated at the same time to form a plurality of gels. Therefore, in the present embodiment, the point different from the second embodiment will be described in detail, and explanations of the same point as the second embodiment will not be provided.

In the present embodiment, as shown in FIG. 7 (a), a plurality of base material pieces 130 are detachably connected to constitute the base material 101. The plurality of base material pieces 130 can be detachably connected by, for example, a method in which physical immobilization is performed with clips or the like, a method in which immobilization is performed by gelation of agarose or the like, and a method in which bonding is performed with a double-faced tape or the like.

Subsequently, as shown in FIG. 7 (b), the same surface treatment as that in the second embodiment may be applied to the base material 101 to form a gel-forming region 106. As one embodiment, the gel-forming region 106 is formed on the base material 101 through reactive ion etching by using a mixed gas of a fluorine based gas and an oxygen gas or an inert gas and an oxygen gas.

[Coating Process]

In the coating process, as shown in FIG. 7 (c), the mixed material 102 of the monomer to form the gels 105 and the photoresist material is applied to the base material 101. That is, the mixed material 102 is applied to the surfaces of the plurality of base material pieces 130 together, and the mixed material 102 is spread on the gel-forming region 106 of the base material 101.

[Gelation Process]

Then, in the gelation process, the external energy is applied to the mixed material 102 to form a gel on each of the base material pieces 130 in such a way that the gel is formed separately from the gel formed on the adjacent base material piece 130. At this time, in order that the external energy is applied to a predetermined region of each of the base material pieces 130, a predetermined photomask may be designed, and the external energy may be applied to the mixed material 102 while the resulting photomask 103 is placed on the mixed material 102. As described above, the monomer in the region irradiated with the external energy is allowed to gel by applying the external energy to the mixed material 102.

[Removal Process]

Next, in the removal process, the mixed material 102 after the gelation process is developed, and the mixed material 102 in the region not irradiated with the external energy is removed. Consequently, as shown in FIG. 7 (d), the gel 105 can be formed on each of the plurality of base material pieces 130 connected.

[Separation Process]

Subsequently, in a separation process, the plurality of base material pieces 130 connected are separated and, thereby, as shown in FIG. 7 (e) and FIG. 8, a plurality of electrophoresis reaction tools 120 can be produced, where a gel 105 is formed on each of the base material pieces 130. In the case where the base materials 101 are mutually immobilized by, for example, the method in which immobilization is performed by gelation of agarose or the like or a method in which bonding is performed with a double-faced tape or the like, it is favorable that the surfaces used for immobilizing the base materials 101 be washed.

In the method for manufacturing an electrophoresis reaction tool, according to the present embodiment, for example, external energy is applied to the mixed material 102 by using a photomask provided with a region of 52 mm×1.15 mm to apply the external energy to the surface (52 mm×1.2 mm) of the base material pieces 130 formed from PMMA of 52 mm wide×23 mm high×1.2 mm thick at a space of 0.1 mm. In this manner, a gel of 52 mm×1.15 mm can be formed on the surface of each of the base material pieces 130.

As described above, a plurality of base material pieces are treated at the same time, and a plurality of gels can be formed in one operation, so that the production efficiency of the electrophoresis reaction tool can be improved.

The present disclosure is not limited to the above-described individual embodiments, various modifications can be made within the scope shown in the claims, and embodiments obtained by appropriate combinations of the individual technical devices disclosed in the different embodiments are included in the technical scope of the present disclosure.

Meanwhile, the present disclosure can be expressed as below. In order to solve the above-described issues, the method for manufacturing an electrophoresis gel, according to the present disclosure, is characterized by including a gradient formation process to add a gel-forming monomer to the first solution containing an initiator to initiate polymerization of the gel-forming monomer on the basis of absorption of the external energy in such a way that a pH gradient or gel-forming monomer concentration gradient is formed and a polymerization initiation process to initiate polymerization of the gel-forming monomer by applying the external energy to the initiator after the gradient formation process and produce the electrophoresis gel.

In the method for manufacturing an electrophoresis gel according to PTL 1, the process to form the gradient (pH gradient or concentration gradient) of the gel-forming monomer and the process to allow the gel-forming monomer to gel are inseparable. Therefore, the gelation may occur while the formation of the gradient in the gel-forming monomer is insufficient. Meanwhile, in the method for manufacturing an electrophoresis gel according to PTL 2, the process to allow the gel-forming monomer to gel is performed by addition of the reagent. In this case, gelation is initiated at the position where the reagent is added and, therefore, gelation cannot be controlled easily and a good gradient may not be formed.

On the other hand, according to the above-described configuration, the process to form the gradient of the gel-forming monomer and the process to allow the gel-forming monomer to gel are performed completely separately, and are not performed at the same time. Also, the polymerization is initiated not by adding a reagent but by applying the external energy, so that the gelation can be uniformly controlled. Therefore, according to the above-described configuration, the gelation can be uniformly initiated after the gradient is formed sufficiently. Consequently, an electrophoresis gel in which a good pH gradient or gel-forming monomer concentration gradient is formed can be produced.

Additionally, in the above-described configuration, the gradient is formed by adding the gel-forming monomer to the liquid (first solution). Consequently, diffusion of the gel-forming monomer is facilitated and a better gradient can be formed as compared with the case where the gel-forming monomer is added to the base material as described in PTL 1 (refer to PTL 2).

In the method for manufacturing an electrophoresis gel, according to the present disclosure, it is favorable that the above-described external energy be at least one of light and heat.

According to the above-described configuration, a photopolymerization initiator or thermal polymerization initiator is used as the above-described initiator, and radicals for gel polymerization can be generated in the gel solution at a controlled timing. As described above, according to the above-described configuration, the timing of gelation can be controlled, so that gelation can be induced after a predetermined gradient is formed reliably in the gel solution, and an electrophoresis gel having highly accurately controlled pH gradient or concentration gradient can be produced.

In the above-described method for manufacturing an electrophoresis gel, the above-described gel-forming monomer may be added by an ink-jet device in the above-described gradient formation process.

According to the above-described configuration, a high-definition pH gradient or gel-forming monomer concentration gradient can be formed.

In the method for manufacturing an electrophoresis gel, according to the present disclosure, a first solution storing process to store the first solution on the base material to support the above-described electrophoresis gel may be included before the above-described gradient formation process.

According to the above-described configuration, a liquid pool is formed on the base material to support the electrophoresis gel, and the gel-forming monomer is added thereto. Therefore, diffusion of the gel-forming monomer is facilitated and a better gradient can be formed.

In the above-described method for manufacturing an electrophoresis gel, a surface treatment process to apply a surface treatment to the above-described base material is included before the above-described first solution storing process, and in the above-described first solution storing process, it is favorable that the first solution be stored in the region which has been subjected to the surface treatment on the above-described base material. Also, in the above-described surface treatment process, it is favorable that a hydrophilic treatment and formation of a plurality of concavities and convexities be performed.

According to the above-described configuration, the region to store the first solution is patterned in a predetermined region on the base material by a surface treatment, and the electrophoresis gel can be formed on the region concerned. In particular, the electrophoresis gel can strongly adhere (bond) to the base material by performing the surface treatment to form a base material surface having high wettability with an aqueous solution and affinity for the gel in the region concerned. As for such surface treatment, for example, hydrophilic surface treatments by using oxygen plasma or the like, plural fine concavities and convexities surface treatments by using nanoimprinting, nanoparticle formation, or the like, and surface treatments with organic compounds analogous to the gel-forming monomer by using graft polymerization or the like can be employed alone or in combination. In particular, the reliability, the reproducibility, and the productivity of the electrophoresis reaction tool can be improved by using the oxygen plasma treatment (hydrophilic treatment) and the nanoparticle formation (nanodot formation treatment).

In the method for manufacturing an electrophoresis gel, according to the present disclosure, it is favorable that the above-described initiator be dispersed in the first solution uniformly.

According to the above-described configuration, the gelation can be performed uniformly, so that a better gradient can be formed.

The apparatus for manufacturing an electrophoresis gel, according to the present disclosure, is characterized by including a gradient-forming device to add a gel-forming monomer to the first solution containing an initiator to initiate polymerization of the gel-forming monomer on the basis of absorption of the external energy in such a way that a pH gradient or gel-forming monomer concentration gradient is formed and a polymerization initiation process to initiate polymerization of the gel-forming monomer by applying the external energy to the initiator and produce the electrophoresis gel.

According to the above-described configuration, the effects equivalent to those of the method for manufacturing an electrophoresis gel, according to the present disclosure, are exerted.

Meanwhile, the present disclosure can be expressed as below. In order to solve the above-described issues, a method for manufacturing an electrophoresis reaction tool, according to the present disclosure, is characterized by including an application process to apply a mixed material of a monomer to form a gel and a photoresist material to a base material, a gelation process to apply radiation energy to a predetermined region of the above-described mixed material applied to the above-described base material and, thereby, allow the above-described monomer in the region irradiated with the radiation energy to gel, and a removal process to develop the above-described mixed material after the above-described gelation process and remove the above-described mixed material in the region not irradiated with the radiation energy.

According to the above-described configuration, in the coating process, the mixed material of the monomer and the photoresist material is applied to the base material and is spread on. Subsequently, in the gelation process, the radiation energy is applied to a predetermined region of the mixed material and, thereby, the monomer in the region irradiated with the radiation energy is allowed to gel. Then, the mixed material after the gelation process is developed and, thereby, the mixed material in the region not irradiated with the radiation energy is removed. In this manner, a gel having a predetermined shape can be formed on the base material.

As described above, the mixed material containing the monomer and the photoresist material is used as the material to form the gel and, thereby, the gel can be formed in only a predetermined region and the material not allowed to gel can be removed easily by performing development after the predetermined region is irradiated with the radiation energy. As a result, a gel having a predetermined shape can be formed easily, so that the production efficiency of the electrophoresis reaction tool can be improved and in addition, the production processes can be simplified.

In the method for manufacturing an electrophoresis reaction tool, according to the present disclosure, it is favorable that the above-described mixed material further contains a radical polymerization initiator which is activated by application of the above-described radiation energy.

According to the above-described configuration, the radical polymerization initiator is activated by application of the radiation energy and radicals are generated. The radical polymerization reaction of the monomer is initiated by generation of the radicals and, therefore, the monomer in only the region irradiated with the radiation energy can gel.

In the method for manufacturing an electrophoresis reaction tool, according to the present disclosure, it is favorable that the above-described monomer and the above-described photoresist material are ejected on the above-described base material by using an ink-jet ejection device in the above-described coating process.

According to the above-described configuration, the monomer and the photoresist material can be applied to the base material favorably. In addition, for example, in the case where the gel having the monomer concentration gradient or pH gradient is formed, the mixed material can be ejected in such a way that the monomer concentration gradient or pH gradient is formed on the base material.

In the method for manufacturing an electrophoresis reaction tool, according to the present disclosure, it is favorable that the base material be subjected to a surface treatment to feed the above-described mixed material to the predetermined region of the above-described base material and allow the gel to adhere to the predetermined region.

According to the above-described configuration, the region to which the mixed material is fed can be controlled because the surface treatment to feed the mixed material to the predetermined region is applied to the base material. Furthermore, the above-described surface treatment is a surface treatment to allow the gel to adhere to the predetermined region, so that the adhesion of the gel produced by gelation of the monomer to the base material is improved and the peeling of the gel can be suppressed.

In the method for manufacturing an electrophoresis reaction tool, according to the present disclosure, it is favorable that a shielding film to block the application of the radiation energy to the above-described mixed material be disposed on the region, to which the radiation energy is not applied, of the above-described mixed material and the radiation energy is applied to the mixed material in the above-described gelation process.

According to the above-described configuration, the shielding film is disposed on the region, to which the radiation energy is not applied, of the mixed material, so that the radiation energy can be applied to only the predetermined region of the mixed material, and application of the radiation energy to the region other than the predetermined region can be prevented. Consequently, only the predetermined region of the mixed material can gel.

In the method for manufacturing an electrophoresis reaction tool, according to the present disclosure, it is favorable that the above-described base material be formed by detachably connecting a plurality of base material pieces, the radiation energy be applied to the mixed material to form a gel on each of the base material pieces in such a way that the gel is formed separately from the gel formed on the adjacent base material piece in the above-described gelation process, and a separation process to separate each of the above-described plurality of base material pieces be included after the above-described removal process.

According to the above-described configuration, the mixed material is applied to the plurality of base material pieces together, a gel is formed on each of the base material pieces in such a way that the gel is formed separately from the gel formed on the adjacent base material piece and, thereafter, the individual base material pieces are separated from each other. Consequently, the plurality of base material pieces can be treated at the same time and, thereby, a plurality of gels can be formed in one operation, so that the production efficiency of the electrophoresis reaction tool can be improved.

The apparatus for manufacturing an electrophoresis reaction tool, according to the present disclosure, is characterized by including an application device to apply a mixed material of a monomer to form a gel and a photoresist material to a base material, an irradiation device to apply radiation energy to a predetermined region of the above-described mixed material applied to the above-described base material and, thereby, allow the above-described monomer in the region irradiated with the radiation energy to gel, and a development device to develop the above-described mixed material after being irradiated with the radiation energy and remove the above-described mixed material in the region not irradiated with the radiation energy.

According to the above-described configuration, the application device applies the mixed material of the monomer and the photoresist material to the base material and spreads thereon. Subsequently, the irradiation device applies the radiation energy to a predetermined region of the mixed material and, thereby, allows the monomer in the region irradiated with the radiation energy to gel. Then, the development device develops the mixed material after the monomer is allowed to gel and, thereby, the mixed material in the region not irradiated with the radiation energy is removed. In this manner, a gel having a predetermined shape can be formed on the base material.

As described above, the mixed material containing the monomer and the photoresist material is used as the material to form the gel and, thereby, the gel can be formed in only the predetermined region and the material not allowed to gel can be removed easily by performing development after a predetermined region is irradiated with the radiation energy. As a result, a gel having a predetermined shape can be formed easily, so that the production efficiency of the electrophoresis reaction tool can be improved and in addition, the production processes can be simplified.

In the apparatus for manufacturing an electrophoresis reaction tool, according to the present disclosure, it is favorable that the above-described application device be an ink-jet ejection device to eject the above-described monomer and the above-described photoresist material on the above-described base material. According to the above-described configuration, the monomer and the photoresist material can be applied to the base material favorably. In addition, for example, in the case where the gel having the monomer concentration gradient or pH gradient is formed, the mixed material can be ejected in such a way that the monomer concentration gradient or pH gradient is formed on the base material.

In the apparatus for manufacturing an electrophoresis reaction tool, according to the present disclosure, it is favorable that a shielding film to block the application of the radiation energy to the above-described mixed material be disposed on the region, to which the radiation energy is not applied by the above-described irradiation device, of the above-described mixed material.

According to the above-described configuration, the shielding film is disposed on the region, to which the radiation energy is not applied, of the mixed material, so that the radiation energy can be applied to only the predetermined region of the mixed material, and application of the radiation energy to the region other than the predetermined region can be prevented. Consequently, only the predetermined region of the mixed material can gel.

An electrophoresis gel material, according to the present disclosure, is characterized by containing the monomer to form the gel and the photoresist material, wherein the electrophoresis gel material is to form a gel having the predetermined shape by allowing only the region irradiated with the radiation energy to gel and removing the region not irradiated with the radiation energy through development.

According to the above-described configuration, as for the electrophoresis gel material, it is possible to allow only the region irradiated with the radiation energy to gel and remove the region not irradiated with the radiation energy through development. Consequently, the gel having the predetermined shape can be formed easily by using the electrophoresis gel material.

### INDUSTRIAL APPLICABILITY

The present disclosure can be utilized in the fields related to the analytical technique through the use of electrophoresis.

Also, the present disclosure can be used for polyacrylamide gel electrophoresis which separates biopolymers, e.g., proteins, DNA, and RNA, or agarose gel electrophoresis and, in particular, can be utilized for electrophoresis having a pH gradient or concentration gradient favorably.

### REFERENCE SIGNS LIST

1 base material
2 gel-forming region
3 first region
4 ink-jet head
5 second region
6 gel solution
7 gel
8 tabular base material
9 scanning direction
10 tray base material
15 placement portion
20 stimulus portion (polymerization initiation device)
30 ejection head (gradient-forming device)
31 head drive portion
32 solution feed portion
33 first solution storing portion
34 second solution storing portion
100 producing apparatus
101 base material
102 mixed material
103 photomask (shielding film)
104 gelation region 104
105 gel
106 gel-forming region
110, 120 electrophoresis reaction tool
130 base material piece

1. A method for manufacturing an electrophoresis gel, characterized by including at least one of:
adding a gel-forming monomer to a first solution containing an initiator to initiate polymerization of the gel-forming monomer by external energy in such a way that a pH gradient or concentration gradient of the gel-forming monomer is formed, as a first process; and
initiating the polymerization of the gel-forming monomer in the first solution, to which the gel-forming monomer has been added, by using the external energy, as a second process.

2. The method for manufacturing an electrophoresis gel, according to claim 1, characterized in that the first process is performed on a base material to support an electrophoresis gel.

3. The method for manufacturing an electrophoresis gel, according to claim 1, characterized in that the gel-forming monomer is added by using an ink-jet device in the first process.

4. The method for manufacturing an electrophoresis gel, according to claim 1, characterized in that the external energy is light or heat.

5. The method for manufacturing an electrophoresis gel, according to claim 2, characterized by further including, before the first process:
applying a surface treatment to the base material, as a third process; and
storing the first solution in a region subjected to the surface treatment, as a fourth process.

6. The method for manufacturing an electrophoresis gel, according to claim 5, characterized in that a hydrophilic treatment and formation of a plurality of concavities and convexities are performed in the fourth process.

7. The method for manufacturing an electrophoresis gel, according to claim 1, characterized by further including:
disposing a shielding film to block the external energy on the first solution, to which the gel-forming monomer has been added, as a fifth process; and
developing the first solution after the second process and removing the first solution in the region shielded from the external energy, as a sixth process.

8. The method for manufacturing an electrophoresis gel, according to claim 7, characterized in that the base material is formed from at least two base material pieces separable from each other.

9. The method for manufacturing an electrophoresis gel, according to claim 8, characterized by further including separating the base material, after the sixth process, into the at least two base material pieces, as a seventh process.

10. An apparatus for manufacturing an electrophoresis gel, characterized by comprising:
an addition device to add a gel-forming monomer to a first solution containing an initiator to initiate polymerization of the gel-forming monomer by external energy in such a way that a pH gradient or concentration gradient of the gel-forming monomer is formed; and
a polymerization initiation device to initiate the polymerization of the gel-forming monomer in the first solution, to which the gel-forming monomer has been added, by using the external energy.

11. The apparatus for manufacturing an electrophoresis gel, according to claim 10, characterized in that the addition device serves on a base material to support the electrophoresis gel.

12. The apparatus for manufacturing an electrophoresis gel, according to claim 10, characterized in that the addition device adds the gel-forming monomer by using an ink-jet system.

13. The apparatus for manufacturing an electrophoresis gel, according to claim 10, characterized in that the external energy is light or heat.

14. The apparatus for manufacturing an electrophoresis gel, according to claim 11, characterized by further comprising, before the addition device:
a surface treatment device to apply a surface treatment to the base material; and
a storing device to store the first solution in a region subjected to the surface treatment.

15. The apparatus for manufacturing an electrophoresis gel, according to claim 14, characterized in that the storing device performs a hydrophilic treatment and formation of a plurality of concavities and convexities.

16. The apparatus for manufacturing an electrophoresis gel, according to claim 10, characterized by comprising:
a disposing device to dispose a shielding film to block the external energy on the first solution to which the gel-forming monomer has been added; and
a removal device to develop the first solution in which the polymerization of the gel-forming monomer has been initiated by the polymerization initiation device and remove the first solution in the region shielded from the external energy by the shielding film.

17. The apparatus for manufacturing an electrophoresis gel, according to claim 16, characterized in that the base material is formed from at least two base material pieces separable from each other.

18. The apparatus for manufacturing an electrophoresis gel, according to claim 17, characterized by comprising a separation device to separate the base material into the at least two base material pieces after the first solution in the region shielded from the external energy is removed.
